(19) United States
(12) Patent Application Publication
(10) Pub. No.: US 2009/0142475 A1
(43) Pub. Date: Jun. 4, 2009

(54) APPARATUS AND METHOD FOR DEPOSITING FILM, AND METHOD OF MANUFACTURING LUMINESCENT DEVICE

(75) Inventors: Shinichiro Morikawa, Aichi (JP); Atsushi Yamada, Aichi (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(73) Assignee: Sony Corporation, Tokyo (JP)

(21) Appl. No.: 12/327,081

(22) Filed: Dec. 3, 2008

(30) Foreign Application Priority Data
Dec. 4, 2007 (JP) 2007-313022

(51) Int. Cl. B05D 5/12; C23C 16/52

(52) U.S. Cl. 427/66; 118/708

(57) ABSTRACT

A film depositing apparatus includes: a chamber in which a substrate is disposed; a gas introducing portion for introducing a reactive gas into the chamber; a gas exhausting portion for exhausting the reactive gas from the chamber; and a control portion for controlling particle exhausting processing for exhausting particles within the chamber from the gas exhausting portion either in a middle of depositing a film on the substrate disposed within the chamber in accordance with a reaction based on the reactive gas, or in a stage of completion of the film deposition. The control portion carries out the control in a way that as the particle exhausting processing performed in a phase of film deposition, the reactive gas is introduced into the chamber at a flow rate more than that in the phase of the film deposition, and is exhausted from the gas exhausting portion.

### CROSS REFERENCES TO RELATED APPLICATIONS

The present invention contains subject matter related to Japanese Patent Application JP 2007-313022 filed in the Japan Patent Office on Dec. 4, 2007, the entire contents of which being incorporated herein by reference.

### BACKGROUND OF THE INVENTION

1. Field of the Invention

The present invention relates to an apparatus and a method for depositing a film each of which is capable of introducing a reactive gas into a chamber to make a reaction based on the reactive gas, thereby carrying out film deposition, and a method of manufacturing a luminescent device.

2. Description of the Related Art

In recent years, development of an organic electro-luminescence (EL) element has been actively advanced as the next generation display device. This organic EL element has a structure that an organic function thin film is sandwiched between electrodes facing each other. Thus, the organic EL element emits lights based on recombination of electrons and holes injected from the respective electrode into the organic function thin film.

Here, the organic function thin film used in the organic EL element is weak in moisture, and thus a voltage remarkably rises at a high temperature and at a high humidity. In addition, even when a passivation film (waterproof film) is formed right over the organic EL element, if a penetration path of the moisture exists in the passivation film or the like, a non-luminescence portion grows in a circular shape from the penetration path to become a dark spot. Moreover, the organic function thin film is weak in temperature as well, and thus a low temperature process at 200° C. or less is required for formation of the organic function thin film.

In order to cope with this situation, recently, it has attracted attention that a silicon nitride (SiNx) film formed by utilizing a Chemical Vapor Deposition (hereinafter referred to as “CVD”) method at the low temperature process at 200° C. or less is used as the passivation layer. For example, Japanese Patent Laid-Open No. 2000-223264 discloses a technique for forming the silicon nitride in the low temperature process.

### SUMMARY OF THE INVENTION

However, when the protective film is formed by utilizing the CVD method in the low temperature process, the reaction based on the reactive gas occurs not only on a substrate, but also between the substrate and a diffuser plate. The reaction occurring between the substrate and the diffuser plate results in that particles are generated between them. Although the particles thus generated float between the substrate and the diffuser plate during the film deposition, when the particles grow to be large or when a high frequency power of the film depositing apparatus is turned off, the particles fall onto the substrate. The particles thus fell are held between a Thin Film Transistor (TFT) substrate and a counter substrate when the TFT substrate and the counter substrate are stuck to each other in the substrate sticking process as the post-process. This causes a fault because the particles thus held damage the TFT substrate and the counter substrate.

In the light of the foregoing, it is therefore desirable to provide an apparatus and a method for depositing a film each of which is capable of removing particles generated in a phase of film deposition by utilizing a chemical vapor deposition method, and a method of manufacturing a luminescent device.

In order to attain the desire described above, according to an embodiment of the present invention, there is provided a film depositing apparatus, including: a chamber in which a substrate is disposed; a gas introducing portion for introducing a reactive gas into the chamber; a gas exhausting portion for exhausting the reactive gas from the chamber; and a control portion for controlling particle exhausting processing for exhausting particles within the chamber from the gas exhausting portion either in a middle of depositing a film on the substrate disposed within the chamber in accordance with a reaction based on the reactive gas, or in a stage of completion of the film deposition.

According to another embodiment of the present invention, there is provided a film depositing method, including the steps of: introducing a gas into a chamber having a substrate disposed therein; forming a film on the substrate in accordance with a reaction based on the reactive gas; and performing particles exhausting processing for exhausting particles within the chamber either in a middle of depositing the film on the substrate or in a stage of completion of the film deposition.

In the above embodiments of the present invention, when the substrate is disposed within the chamber and the film is disposed on the substrate in accordance with the reaction based on the reactive gas introduced into the chamber, the particles within the chamber are exhausted either in the middle of the film deposition or in the stage of completion of the film deposition. Therefore, the particles generated in accordance with the reaction other than the reaction for the deposition of the film on the substrate can be exhausted from the chamber.

In addition, according to still another embodiment of the present invention, there is provided a luminescent device manufacturing method of forming a protective film on a luminescent film formed on a substrate within a chamber by utilizing a chemical vapor deposition method. The method includes the steps of: performing particle exhausting processing for exhausting particles within the chamber either in a middle of forming the protective film by utilizing the chemical vapor deposition method or in a stage of completion of the formation of the protective film; and taking out the substrate from the chamber.

In the embodiment of the present invention, when the substrate is disposed within the chamber, and the protective film is formed on the luminescent film formed on the substrate by utilizing the chemical vapor deposition method, the particles within the chamber are exhausted either in the middle of formation of the protective film or in the stage of completion of the formation of the protective film. Therefore, the particles generated in accordance with the reaction other than the reaction for the formation of the protective film on the substrate can be exhausted from the chamber. This results in that the protective film can be formed without being influenced by the particles.

Accordingly, according to an embodiment of the present invention, the process for removing the particles is introduced, which results in that it is possible to suppress the fault due to the particles generated in the post-process.

### BRIEF DESCRIPTION OF THE DRAWINGS

FIG. 1 is a schematic cross sectional view explaining a film depositing apparatus according to an embodiment of the present invention;

FIGS. 2A to 2G are respectively schematic cross sectional views explaining a film depositing method according to an embodiment of the present invention;

FIGS. 3A to 3C are respectively schematic diagrams showing a construction for carrying out a particle removing process in comparison with that in a related art example; and

FIGS. 4A and 4B are respectively a schematic cross sectional view of a luminescent element (organic EL element) manufactured by using the film depositing apparatus of the embodiment, and by utilizing the film depositing method of the embodiment, and an enlarged view of a luminescence function layer in the luminescent element shown in FIG. 4A.

### DETAILED DESCRIPTION OF THE PREFERRED EMBODIMENTS

The preferred embodiments of the present invention will be described in detail hereinafter with reference to the accompanying drawings.

<Film Depositing Apparatus>

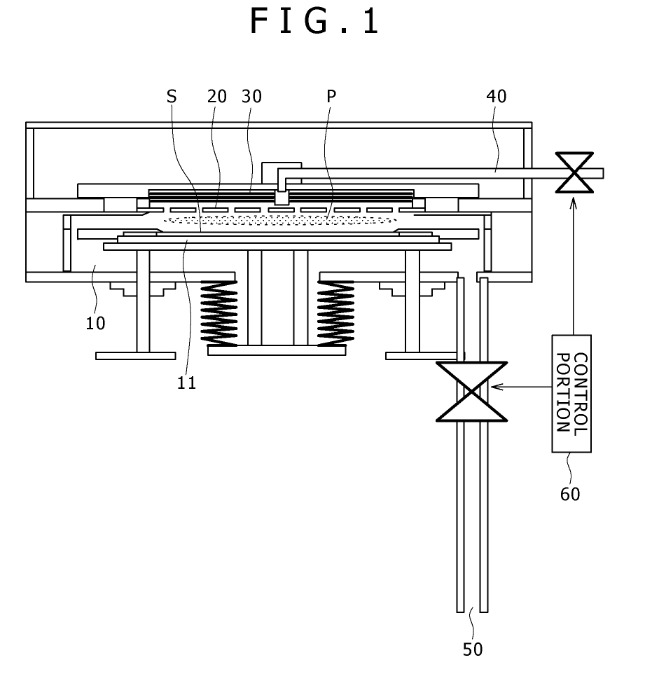

FIG. 1 is a schematic cross sectional view explaining a film depositing apparatus according to an embodiment of the present invention. That is to say, the film depositing apparatus includes a chamber 10 in which film depositing processing is performed, a stage 11, a shower plate 20, a diffuser plate 30, a gas supplying portion 40, a gas exhausting portion 50, and a control portion 60. In this case, the stage 11 fixes and holds a substrate S for which the film depositing processing is performed within the chamber 10. The shower plate 20 supplies a reactive gas for film depositing processing to the chamber 10. The diffuser plate 30 causes the reactive gas to diffuse within the chamber 10, and the gas supplying portion 40 supplies the reactive gas to the chamber 10. The gas exhausting portion 50 exhausts the reactive gas from the chamber 10. In addition, the control portion 60 controls valves of the gas supplying portion 40 and the gas exhausting portion 50, an amount of reactive gas supplied, an amount of reactive gas exhausted, and pressures in the gas supplying portion 40 and the gas exhausting portion 50.

Of these constituent elements, the chamber 10 is held in its inside in an airtight state. Also, the chamber 10 is further provided with a pressure reducing section (not shown) configured to exhaust the gas existing inside the chamber 10 to reduce the pressure in the chamber 10. The pressure reducing section, for example, is composed of a turbo-molecular pump which is provided with a control mechanism for holding the internal pressure constant.

In addition, the stage 11 includes a chuck function (not shown) of fixing the substrate S placed thereon, and a heating section configured to heat the substrate S placed on and fixed to its upper portion. The heating section, for example, is composed of a heater (not shown) for performing electrical heating, and is buried within the stage 11.

The shower plate 20 is disposed so as to face the stage 11 within the chamber 10. The shower plate 20 has a size enough to be disposed within the chamber 10 so as to face the entire surface on the substrate S disposed on the stage 11. In addition, a plurality of holes for uniformly supplying the reactive gas introduced from the gas introducing portion 40 into the chamber 10 through the diffuser plate 30 onto the substrate S are bored through the shower plate 20.

In the film depositing apparatus of the embodiment, in a state in which the substrate S is placed on the stage 11 within the chamber 10, the reactive gas is introduced from the gas introducing portion 40 into the chamber 10, and plasma P is generated by applying a high frequency power to the chamber 10. As a result, a film can be formed on the substrate S in accordance with a reaction based on the reactive gas.

In particular, in the film depositing apparatus of the embodiment, the opening and closing of the valves of the gas introducing portion 40 and the gas exhausting portion 50 are controlled by the control portion 60. As a result, particles generated within the chamber 10 can be exhausted to the outside.

Here, an organic function thin film used in an organic EL element is weak in moisture, and thus a voltage remarkably rises at a high temperature and at a high humidity. Thus, when a passivation film (waterproof film) desired to be formed on the organic function thin film is formed, for example, it is necessary to form the passivation film on the organic function thin film in a low temperature process at 200° C. or less.

When the CVD is carried out in such a low temperature process, the reaction based on the reactive gas occurs not only on the substrate S, but also between the substrate S and the diffuser plate 30 to generate particles in the chamber 10. As a result, the particles thus generated float within the chamber 10. In this embodiment, in order to exhaust the particles generated in the chamber 10 to the outside of the chamber 10, the operation for supplying the gas, and the operation for exhausting the gas are controlled by the control portion 60.

Specifically, particle exhausting processing for exhausting the particles within the chamber 10 from the gas exhausting portion 50 either in the middle of formation of a film on the substrate S disposed within the chamber 10 in accordance with the reaction based on the reactive gas, or in the step of completion of the film deposition is controlled by the control portion 60.

That is to say, the control portion 60 performing the processing for not only introducing the reactive gas for deposition of the film on the substrate S, but also exhausting the reactive gas from the gas exhausting portion 50 either in the middle of the film deposition or in the stage of completion of the film deposition. When the reactive gas is exhausted from the gas exhausting portion 50 in the middle of the film deposition, the film deposition is carried out in a state in which an introduction pressure and a flow rate of the reactive gas are increased as compared with those in the normal film deposition. On the other hand, when the reactive gas is exhausted from the gas exhausting portion 50 in the stage of completion of the film deposition, the reactive gas is exhausted before the high frequency power being applied to the chamber 10 is turned off. The reason for this is because the floating particles are prevented from dropping to be stuck to the substrate S due to turn-off of the high frequency power.

The exhaust of such a reactive gas results in that the particles floating within the chamber 10 can be forcibly exhausted to the outside of the chamber 10, and thus can also be prevented from being stuck to the substrate S.

In addition, the control portion 60 may also carry out the control as the particle exhausting processing in a way that the reactive gas is introduced into the chamber 10 at a larger flow rate than that in the phase of the film deposition and is exhausted from the gas exhausting portion 50. As a result, the reactive gas within the chamber 10 can be efficiently exhausted to the outside of the chamber 10, and thus the particles can also be efficiently exhausted.

In addition, the control portion 60 may also carry out the control as the particle exhausting processing in a way that the pressure when the reactive gas is introduced into the chamber 10 is made higher than that in the phase of the film deposition. As a result, the reactive gas can be efficiently introduced into and exhausted from the chamber 10, and thus the particles can also be efficiently exhausted to the outside of the chamber 10.

In addition, as the particle exhausting processing after completion of the film deposition, the control portion 60 may carry out the air blow for the surface of the substrate S. In this case, the air used in the air blow is cleaned to become clean air through a suitable filter.

Moreover, while the film is deposited on the substrate S, the control portion 60 may carry out the particle exhausting processing plural times. That is to say, the process may also be adopted such that in the middle of depositing a film after a predetermined reactive gas is introduced for the purpose of forming one sheet of film, the particle exhausting processing is performed in which either the pressure or flow rate of the reactive gas is made larger than that in the normal film deposition, and thereafter, in the stage of returning the film deposition conditions back to the normal ones, and carrying out the film deposition partway, the particle exhausting gas processing is performed again. In this case, such a process may be repeatedly carried out. Thus, the particle exhausting processing may be performed plural times while one sheet of film is formed. As a result, even in the case of formation of one sheet of film, it is possible to reliably prevent the particles from being stuck to the substrate.

It is noted that although the film depositing apparatus shown in FIG. 1 carries out the film deposition in the state in which the substrate S is placed on and fixed to the stage 11, an apparatus construction may also be adopted such that the film deposition is carried out while the substrate S is carried.

In addition, a process may also be adopted such that a particle counter or an optical sensor is provided inside the chamber 10, and the control portion 60 performs the particle exhausting processing in the stage of counting the certain number of particles. Specifically, when the number of particles within the chamber 10 exceeds a threshold previously set, or when the size of each of the particles becomes such one as to exert an influence on the performance of the element to be manufactured, the particle exhausting processing is automatically performed. Here, with regard to the latter case, there are given the case where the size of each of the particles becomes larger than the thickness of the film being deposited, or becomes larger than the thickness of the film formed so as to follow the film deposition concerned, and so forth.

<Film Depositing Method>

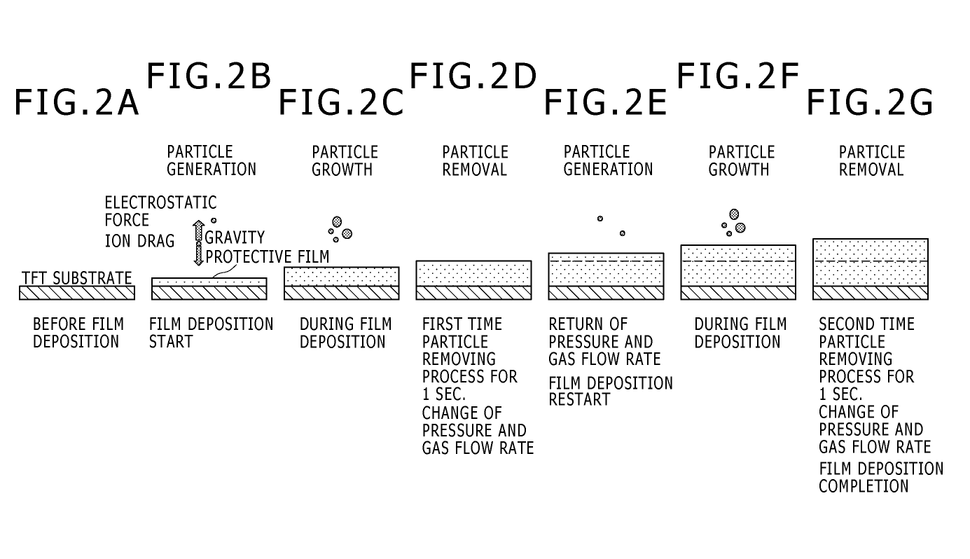

FIGS. 2A to 2G are respectively schematic cross sectional views explaining a film depositing method according to an embodiment of the present invention. In these figures, the film deposition is carried out in the order of FIG. 2A to FIG. 2G. The feature of the film depositing method of the embodiment is that the particles generated between the substrate and the diffuser plate are removed away before falling onto the substrate.

With regard to a method of removing any of the particles, a particle removing process (particle exhausting processing) is added to the main process in the middle of the process for depositing the film such as a protective film. The particle removing process is such that either the pressure or the gas flow rate is changed during the process for depositing the film such as a protective film, and under this condition, the film deposition is continuously carried out. The particle removing process is carried out one or more times for deposition of one sheet of film.

In addition, the particle removing process is preferably, necessarily carried out before completion of the film deposition, and after completion thereof. In addition, a process may also be adopted as the particle removing process after completion of the film deposition such that the air blow is carried out for the surface of the substrate to remove away the particles lying thereon. The particle removing process is preferably carried out for 0.1 seconds or more from a viewpoint of the reliable particle removal.

Next, the film depositing method will be described in detail with reference to FIGS. 2A to 2G. It is noted that in the embodiment shown in FIGS. 2A to 2G, the particle removing process is carried out twice in the deposition of one sheet of film. Firstly, the substrate, as a subject of the film deposition, such as a TFT substrate is disposed within the chamber (refer to FIG. 2A). Next, a film such as a protective film starts to be deposited on the substrate by applying the high frequency power to the chamber concurrently with the introduction of the reactive gas into the chamber (refer to FIG. 2B).

When the film deposition starts to be carried out, the particles are generated between the substrate and the diffuser plate (refer to FIG. 2B). The particles do not drop, but float within the chamber because an electrostatic force and an ion drag opposing to the gravity act on the particles. When the film deposition is continuously carried out, the particles grow so as to follow the film deposition (refer to FIG. 2C).

Next, the pressure and gas flow rate of the reactive gas introduced into the chamber are changed, and under this condition, the first time particle removing process, for example, is carried out for 1.0 second (refer to FIG. 2D). As a result, the particles generated in this stage are removed away from the chamber (refer to FIG. 2D).

After that, the pressure and gas flow rate of the reactive gas are returned back to the normal ones, and under this condition, the normal film deposition restarts to be carried out (refer to FIG. 2E). As a result, the particles are generated in the chamber again (refer to FIG. 2E). When the film deposition is further continuously carried out, the particles also grow so as to follow the film deposition (refer to FIG. 2F).

Also, the pressure and gas flow rate of the reactive gas are changed in the phase of completion of the film deposition, and under this condition, the second time particle removing process, for example, is carried out for 1.0 second (refer to FIG. 2G). As a result, the particles generated in this stage are removed away from the chamber (refer to FIG. 2G).

Note that, in the film depositing method described above, the film deposition is carried out in accordance with the flow of (1) the film deposition starts to be carried out→(2) the protective film grows→(3) the first time particle removing process is carried out for 1.0 second→(4) the pressure and gas flow rate of the reactive gas are returned back to the normal ones, and the film deposition restarts to be carried out→(5) the protective film grows→(6) the second time particle removing process is carried out for 1.0 second→(7) the film deposition is completed. However, the film deposition may also be carried out in accordance with any of other suitable flows other than the flow described above. Hereinafter, outlines of other suitable flows will be described.

(Flow of Carrying Out Particle Removing Process Once)

(1) The film deposition starts to be carried out→(2) the protective film grows→(3) the first time particle removing process is carried out for 1.0 second→(4) the film deposition is completed.

In the above flow, the particle removing process is carried out only once for a time period from start of the film deposition to completion of the film deposition. Thus, the above flow is effective when the film deposition is carried out for a relatively short time period. That is to say, when the film deposition time is short, the degree of the growth of each of the particles is small. Therefore, the particles can be sufficiently exhausted even by carrying out the particle removing process once.

(Flow of Carrying Out Particle Removing Process Thrice)

(1) The film deposition starts to be carried out→(2) the protective film grows→(3) the first time particle removing process is carried out for 1.0 second→(4) the pressure and the gas flow rate of the reactive gas are returned back to the normal ones, and the film deposition restarts to be carried out→(5) the protective film grows→(6) the second time particle removing process is carried out for 1.0 second→(7) the pressure and gas flow rate of the reactive gas are returned back to the normal ones, and the film deposition restarts to be carried out→(8) the protective film grows→(9) the third time particle removing process is carried out for 1.0 second→(10) the film deposition is completed.

In the flow described above, the particle removing process is carried out thrice for a time period from start of the film deposition to completion of the film deposition. Thus, the above flow is effective when the film deposition is carried out for a relatively long time period. That is to say, when the film deposition time is long, the degree of the growth of each of the particles is large. Therefore, the particles can be sufficiently exhausted even by carrying out the particle removing process plural times.

(Flow of Carrying Out Particle Removing Process for 0.1 Seconds)

(1) The film deposition starts to be carried out→(2) the protective film grows→(3) the first time particle removing process is carried out for 0.1 second→(4) the pressure and gas flow rate of the reactive gas are returned back to the normal ones, and the film deposition restarts to be carried out→(5) the protective film grows→(6) the second time particle removing process is carried out for 0.1 second→(7) the film deposition is completed.

Although, in the above flow, the particle removing process is carried out twice for a time period from start of the film deposition to completion thereof, one particle removing process is carried out for a short time period of 0.1 seconds. Although in the particle removing process, the pressure and gas flow rate of the reactive gas are changed from those in the phase of the normal film deposition, an influence exerted on the film deposition by this change can be suppressed to a minimum.

(Flow of Combining Particle Removing Process with Film Quality Changing Process (Neither Pressure nor Gas Flow Rate is Returned Back to Normal Ones))

(1) The film deposition starts to be carried out→(2) the protective film grows→(3) the first time particle removing process is carried out for 1.0 second→(4) the film deposition restarts to be carried out while the pressure and gas flow rate of the reactive gas are held as they are→(5) the protective film grows→(6) the second time particle removing process is carried out for 1.0 second→(7) the film deposition is completed.

Although, in the above flow, the particle removing process is carried out twice for a time period from start of the film deposition to completion thereof, the film deposition is continuously carried out while the conditions of the first time particle removing process are kept as they are. As a result, it is possible to carry out the particle removing process together with a process for changing a film to be formed halfway.

(Flow of Changing Only Pressure)

(1) The film deposition starts to be carried out→(2) the protective film grows→(3) the first time particle removing process is carried out for 1.0 second→(4) only the pressure of the reactive gas is returned back to the normal one, and the film deposition restarts to be carried out→(5) the protective film grows→(6) the second time particle removing process is carried out for 1.0 second→(7) the film deposition is completed.

Although, in the above flow, the particle removing process is carried out twice for a time period from start of the film deposition to completion thereof, only the pressure of the reactive gas is changed as the particle removing process from one in the normal film deposition conditions. As a result, it is possible to suppress an influence exerted on the film deposition by carrying out the condition changing from those in the phase of the normal film deposition.

(Flow of Changing Only Gas Flow Rate (0 Sccm is also Possible))

(1) The film deposition starts to be carried out→(2) the protective film grows→(3) the first time particle removing process is carried out for 1.0 second→(4) only the gas flow rate of the reactive gas is returned back to the normal one and the film deposition restarts to be carried out→(5) the protective film grows→(6) the second time particle removing process is carried out for 1.0 second→(7) the film deposition is completed.

Although, in the above flow, the particle removing process is carried out twice for a time period from start of the film deposition to completion thereof, only the gas flow rate of the reactive gas is changed as the particle removing process from one in the normal film deposition conditions. As a result, it is possible to suppress an influence exerted on the film deposition by changing the conditions from those in the phase of the normal film deposition.

(Flow of Particle Removing Process After Completion of Film Deposition)

(1) The film deposition starts to be carried out→(2) the protective film grows→(3) the first time particle removing process is carried out for 1.0 second→(4) the pressure and gas flow rate of the reactive gas are returned back to the normal ones, and the film deposition restarts to be carried out→(5) the protective film grows→(6) the film deposition is completed→(7) the particle removing process is carried out after completion of the film deposition by performing the air blow.

In the above flow, the particle removing process is carried out once in the middle of the film deposition and the particle removing process is carried out after completion of the film deposition by performing the air blow. The particles can also be removed away even by performing the simple air blow instead of changing the pressure and flow rate of the reactive gas.

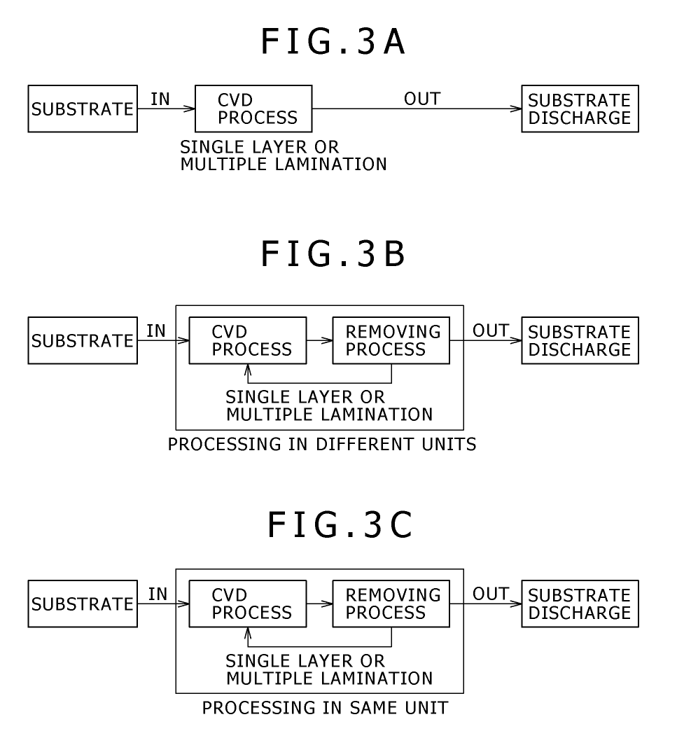

Here, the particle removing process applied to the film depositing method of the embodiment may be carried out either in the same film deposition apparatus or in another unit. FIGS. 3A to 3C are respectively schematic diagrams showing a construction for carrying out the particle removing process in comparison with that in a related art example. The related art example shown in FIG. 3A adopts a process for discharging the substrate from the film depositing apparatus after the substrate is carried into the film depositing apparatus and the film depositing processing is performed by the CVD.

On the other hand, next two examples of constitutions for carrying out the particle removing process are given in the embodiment. Firstly, in the example shown in FIG. 3B, the substrate is carried into the film depositing apparatus, and the film depositing processing is performed in a unit for performing the CVD. After that, the substrate is carried into a next unit, and the particle removing process is carried out in the next unit. The unit for performing the film depositing processing and the unit for performing the particle removing process are different from each other. However, these units are communicated with each other through a carry path (carry unit) for the substrate, so that a plurality sheet of substrates can be continuously processed. Here, the unit is a unit of an apparatus construction capable of performing predetermined processing, and for example, means a construction including one chamber.

Next, in the example shown in FIG. 3C, the substrate is carried into a unit in the film depositing apparatus, and the film depositing processing by the CVD is performed in the unit. Also, the film deposition conditions are changed and in this state, the particle removing process is carried out within the same unit.

As has been described, in the embodiment, it is possible to respond not only to the form in which the film depositing process by the CVD, and the particle removing processing are performed in the different units, respectively, but also to the form in which these processes are carried out within the same unit.

<Method of Manufacturing Luminescent Element>

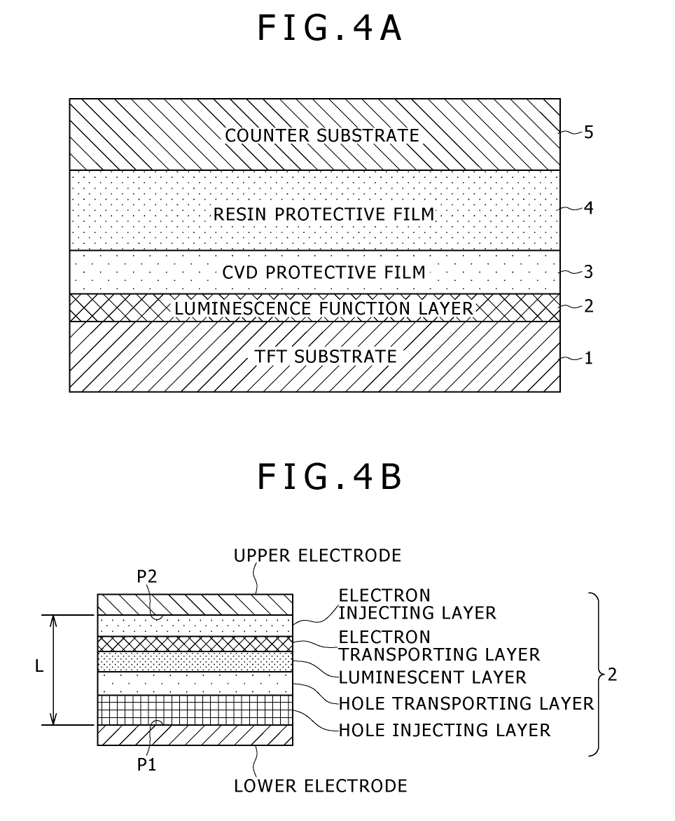

FIGS. 4A and 4B are respectively a schematic cross sectional view of a luminescent element (organic EL element) manufactured by using the film depositing apparatus of the embodiment, and by utilizing the film depositing method of the embodiment, and an enlarged view of a luminescence function layer in the luminescent element shown in FIG. 4A. As shown in FIG. 4A, the organic EL element is composed of a TFT substrate 1, an organic function layer (luminescence function layer) 2, a CVD protective film 3, a resin protective film 4, and a counter substrate 5.

The TFT substrate 1 is provided with a TFT for performing switching for a lower electrode, and the luminescence function layer 2 as the organic function thin film is laminated on the TFT substrate 1. In this case, the luminescence function layer 2 as the organic function thin film is formed by mainly laminating an organic material on the lower electrode. In addition, the CVD protective film 3 is formed on the luminescence function layer 2 by using the film depositing apparatus of the embodiment, and by utilizing the film depositing method of the embodiment. Also, the counter substrate 5 is disposed on the CVD protective film 3 through the resin protective film 4.

One of the lower electrode and an upper electrode is structured as an anode, and the other of the lower electrode and the upper electrode is structured as a cathode. In this case, the lower electrode is structured as the anode, and the upper electrode is structured as the cathode.

In addition, the lower electrode is formed in a pattern so as to correspond to pixels, respectively, whereas the upper electrode is provided as a common electrode to the pixels on the luminescence function layer 2.

In addition, as shown in the enlarged view of FIG. 4B, the luminescence function layer 2, for example, is formed by laminating a hole injecting layer, a hole transporting layer, a luminescent layer, an electron transporting layer, and an electron injecting layer in order from the lower electrode side. Of these layers, any of the layers other than the luminescent layer may be formed as may be necessary.

In such a luminescence function layer 2, at least luminescent layers for emitting lights having respective wavelengths are formed in a pattern from materials selected so as to correspond to elements, respectively, in the organic EL elements corresponding to the respective colors.

The organic EL element having the lamination structure as described above is structured in the form of a resonator structure in which the lights generated in the luminescence function layer 2 are made to resonate between the lower electrode composed of a reflecting electrode, and the upper electrode made of a semi-transmissive and semi-reflective material to be taken out from the upper electrode side.

That is to say, each of these organic EL elements has the resonator structure in which an interface on the luminescence function layer 2 side in the lower electrode acts as a first end portion, an interface on the luminescence function layer 2 side in the upper electrode acts as a second end portion, and the luminescence function layer 2 acts as a resonance portion. When each of the organic EL elements is structured so as to have the resonator structure in the manner described above, the lights generated in the luminescence function layer 2 causes a multiple interference, and the luminescence function layer 2 acts as a sort of narrow band filter. As a result, a half bandwidth of a spectrum of the lights taken out from the side of the upper electrode made of the semi-transmissive and semi-reflective material decreases, thereby making it possible to enhance the color purity.

In order to attain this, it is important that an optical distance L between the first end portion (reflecting surface) P1 of the resonator, and the second end portion (semi-transmissive surface) P2 fulfills Expression (1), and a resonance wavelength (a peak wavelength of the spectrum of the lights taken out) of the resonator, and a peak wavelength of the spectrum of the lights desired to be taken out are made to agree with each other:

(2L)/λ+Φ/(2n)=m (1)

where L is the optical distance between the first end portion P1 and the second end portion P2, m is the order (0 or a natural number), Φ is a sum of phase shift Φ1 of a reflected light caused in the first end portion P1 and phase shift Φ2 of the reflected light caused in the second end portion P2 (Φ=Φ1+Φ2) [rad], and λ is a peak wavelength of the spectrum of the lights desired to be taken out from the side of the second end portion P2. It is noted that L and λ have a common unit, and for example, have a unit of [nm] as the common unit.

The lower electrode composing the first end portion P1 of such a resonator structure has preferably a reflectivity as high as possible in terms of enhancement of a luminous efficiency.

In addition, the lower electrode can be made of a metal or metallic oxide having a relatively large work function because it is used as the anode. Such a lower electrode has a thickness of 30 to 2000 nm in the lamination direction, and thus is made of a silver alloy film, an alloy film of aluminum and neodymium, or the like.

On the other hand, the upper electrode composing the second end portion P2 of the resonator structure is used as the semi-transmissive reflective layer. Thus, it is preferable in terms of reduction of a loss due to absorption that a sum of a reflectivity and a transmittance becomes as near 100% as possible, and an absorptivity becomes as small as possible.

In addition, the upper electrode is the electron injecting electrode used as the cathode. Therefore, a barrier for electron injection to the luminescence function layer 2 is preferably small, and the upper electrode is preferably made of a metal having a small work function. Moreover, even when the upper electrode is thin to the extent that the loss due to the light absorption can be prevented as described above, it needs to have a conductivity enough to supply the holes to the luminescence function layer 2 side, thereby acting as the electrodes on that basis.

A metal film of which such an upper electrode is formed is preferably a metallic thin film made of an alloy containing therein an alkali metal or an alkali earth metal such as magnesium (Mg), calcium (Ca) or sodium (Na), and silver (Ag). In particular, the metal film of which such an upper electrode is formed is more preferably a metallic thin film made of an alloy containing therein magnesium (Mg) and silver (Ag).

The reason for this is that the metallic thin film made of the alloy containing therein magnesium (Mg) and silver (Ag) is optimal as the light-taking out side electrode in the light resonator structure because it can be stably formed by performing the vacuum evaporation, and even when being formed as a thin film having a thickness of about 5 to 10 nm, it can drive an organic electro-luminescence element. In addition, the reason for this is that the upper electrode made of the alloy containing therein magnesium (Mg) and silver (Ag) has the less defect and thus the luminescence having the high reliability can be obtained because it can be simply formed by utilizing the film depositing method, such as a resistance heating evaporation method, with which the less damage is caused in the organic film.

Also the layers composing the luminescence function layer 2 provided between the lower electrode and upper electrode as described above are structured from the lower layer side as follows.

The hole injecting layer is provided for enhancement of the hole injection efficiency. Such a hole injecting layer is made of the known material, for example, such as a hexaazatriphenylene derivative, an aromatic amine derivative or the like. A thickness of the hole injecting layer, as an example, is in the range of 4 to 100 nm.

The hole transporting layer is provided for enhancement of the efficiency of transporting the holes to the luminescent layer. Such a hole transporting layer, for example, is made of bis-[(N-naphthyl)-N-phenyl]benzidine (α-NPD). Also, a thickness of the hole transporting layer, as an example, is in the range of 5 to 300 nm.

When an electric field is applied across the luminescent layer, the electrons and the holes are recombined with each other, so that the luminescent layer emits the lights. The luminescent layers are different in structure from one another so as to correspond to the organic EL element (r), the organic EL element (g), and the organic EL element (b) corresponding to R, G and B, respectively.

The luminescent layer of the red luminescent device, for example, is made of a material formed by mixing Alq3 with 40 vol. % 2,6-bis-[4-[N-(4-methoxyphenyl)-N-phenyl]aminostyryl]naphthalene-1,5-dicarbonitrile (BSN-BCN). A thickness of the luminescent layer of the red luminescent device, as an example, is in the range of 10 to 100 nm.

The luminescent layer of the green luminescent device, for example, is made of a material formed by mixing Alq3 with 3 vol. % coumarin 6. A thickness of the luminescent layer of the green luminescent device, for example, is in the range of 10 to 100 nm.

The luminescent layer of the blue luminescent device, for example, is made of a material formed by mixing 9,10-di-(2-naphthyl)anthracene (ADN) with 1 vol. % perylene. A thickness of the luminescent layer of the blue luminescent device, for example, is in the range of 10 to 100 nm.

The electron transporting layer is provided for enhancement of the efficiency of transporting the electrons to the luminescent layer. Such an electron transporting layer, for example, is made of Alq3. A thickness of the electron transporting layer, as an example, is in the range of 5 to 300 nm.

The electron injecting layer is provided for enhancement of the efficiency of injecting the electrons to the luminescent layer. Such an electron injecting layer, for example, is preferably made of an alloy of an alkali metal or an alkali earth metal such as lithium (Li), magnesium (Mg) or calcium (Ca), and a metal such as silver (Ag), aluminum (Al) or indium (In). Specifically, the electron injecting layer is preferably made of an Mg—Ag alloy.

In addition, the electron injecting layer is preferably made of a compound of an alkali metal or an alkali earth metal such as lithium (Li), magnesium (Mg) or calcium (Ca), and halogen such as fluorine or bromine, or oxygen. Specifically, the electron injecting layer is also preferably made of LiF. Moreover, the electron injecting layer may also be made of a material formed by adding an alkali metal such as magnesium (Mg) to an organic material having an electron transporting property such as 8-quinolinol aluminum complex (Alq3). The electron injecting layer may have a structure obtained by laminating the two or more kinds of films of these films one upon another.

With the electron injecting layer, for example, is made of a halide of an alkali metal such as LiF, a halide of an alkali earth metal, an oxide of an alkali metal, or an oxide of an alkali earth metal, a thickness of such an electron injecting layer is preferably in the range of 0.3 to 1.3 nm. The reason for this is because the driving voltage can be reduced and thus the luminescent efficiency can also be enhanced.

In addition, the CVD protective film 3 covering the organic EL element is a passivation film made of a transparent dielectric material. For example, the CVD protective film 3 is made of a silicon oxide (SiO2), a silicon nitride (SiN) or the like. A thickness of the CVD protective film 3 is in the range of about several tens of nanometers to about several micrometers (for example, 5 μm).

In addition, the resin protective film 4 formed on the CVD protective film 3, for example, is made of a resin material such as an epoxy resin, an acrylic resin, or the like. A thickness of the resin protective film 4 is in the range of about several tens of nanometers to about several tens of micrometers (for example, 30 μm).

In the embodiment, the particle removal is carried out in the process for forming the CVD protective film 3. Therefore, it is possible to prevent the particles each size of which exceeds the thickness of the CVD protective film 3 in the phase of the formation of the CVD protective film 3 from being stuck to the TFT substrate 1. Also, it is possible to prevent the particles each size of which exceeds the thickness of the resin protective film 4 from being stuck to the CVD protective film 3. As a result, it is possible to manufacture the organic electro-luminescence (EL) element having the high reliability.

It should be understood by those skilled in the art that various modifications, combinations, sub-combinations and alterations may occur depending on design requirements and other factors insofar as they are within the scope of the appended claims or the equivalents thereof.

What is claimed is:

1. A film depositing apparatus, comprising:
a chamber in which a substrate is disposed;
a gas introducing portion for introducing a reactive gas into the chamber;
a gas exhausting portion for exhausting the reactive gas from said chamber; and
a control portion for controlling particle exhausting processing for exhausting particles within said chamber from said gas exhausting portion either in a middle of depositing a film on said substrate disposed within said chamber in accordance with a reaction based on the reactive gas, or in a stage of completion of the film deposition.

2. The film depositing apparatus according to claim 1,
wherein said control portion carries out the control in a way that as the particle exhausting processing performed in a phase of film deposition, the reactive gas is introduced into said chamber at a flow rate more than that in the phase of the film deposition, and is exhausted from said gas exhausting portion.

3. The film depositing apparatus according to claim 1,
wherein said control portion carries out the control in a way that as the particle exhausting processing performed in a phase of film deposition, a pressure at which the reactive gas is introduced into said chamber is made higher than that in a phase of film deposition.

4. The film depositing apparatus according to claim 1,
wherein said control portion carries out the control in a way that as the particle exhausting processing performed in a phase of film deposition, air is introduced into said chamber and is exhausted from said gas exhausting portion.

5. The film depositing apparatus according to claim 1,
wherein said control portion carries out the particle exhausting processing in a phase of film deposition plural times.

6. A film depositing method, comprising the steps of:
introducing a gas into a chamber having a substrate disposed therein;
forming a film on said substrate in accordance with a reaction based on the reactive gas; and
performing particle exhausting processing for exhausting particles within said chamber either in a middle of depositing said film on said substrate or in a stage of completion of said film deposition.

7. The film depositing method according to claim 6,
wherein as the particle exhausting processing performed in a phase of film deposition, the reactive gas is introduced into said chamber at a flow rate more than that in the phase of the film deposition, and is exhausted from said gas exhausting portion.

8. The film depositing method according to claim 6,
wherein as the particle exhausting processing performed in a phase of film deposition, a pressure at which the reactive gas is introduced into said chamber is made higher than that in a phase of film deposition.

9. The film depositing method according to claim 6,
wherein as the particle exhausting processing performed in a stage of completion of the film deposition, air is introduced into said chamber and is exhausted from said gas exhausting portion.

10. The film depositing method according to claim 6,
wherein the particle exhausting processing in a phase of film deposition is carried out plural times.

11. A luminescent device manufacturing method of forming a protective film on a luminescent film formed on a substrate by utilizing a chemical vapor deposition method, said method comprising the steps of:
performing particle exhausting processing for exhausting particles within said chamber either in a middle of forming said protective film by utilizing the chemical vapor deposition method or in a stage of completion of the formation of said protective film; and
taking out said substrate from the chamber.

12. The luminescent device manufacturing method according to claim 11,
wherein as the particle exhausting processing performed in a middle of formation of said protective film, the reactive gas is introduced into said chamber at a flow rate more than that in a phase of formation of said protective film, and is exhausted from said gas exhausting portion.

13. The luminescent device manufacturing method according to claim 11,
wherein as the particle exhausting processing performed in a middle of formation of said protective film, a pressure at which the reactive gas is introduced into said chamber is made higher than that in a phase of formation of said protective film.

14. The luminescent device manufacturing method according to claim 11,
wherein as the particle exhausting processing performed in a stage of completion of the formation of said protective film, air is introduced into said chamber and is exhausted from said gas exhausting portion.

15. The luminescent device manufacturing method according to claim 11,
wherein the particle exhausting processing performed in a middle of formation of said protective film is carried out plural times.
